(19) United States
(12) Patent Application Publication
(10) Pub. No.: US 2023/0106013 A1
(43) Pub. Date: Apr. 6, 2023

(54) PACKAGE SUBSTRATE AND SEMICONDUCTOR PACKAGE INCLUDING THE SAME

(71) Applicant: SAMSUNG ELECTRONICS CO., LTD., Suwon-si (KR)

(72) Inventor: Seungmin KIM, Asan-si (KR)

(21) Appl. No.: 17/876,847

(22) Filed: Jul. 29, 2022

(30) Foreign Application Priority Data
Oct. 1, 2021 (KR) 10-2021-0130827

(51) Int. Cl. H01L 23/498; H01L 21/48

(52) U.S. Cl. CPC H01L 23/49822; H01L 23/49838; H01L 21/4857; H01L 21/481; H01L 23/3128

(57) ABSTRACT

A package substrate includes a dielectric layer, a conductive pad and a wiring pattern on the dielectric layer, a protection layer on the dielectric layer, the protection layer covering the wiring pattern, and an undercut region between facing surfaces of the dielectric layer and the protection layer, the undercut region exposing a sidewall of the wiring pattern, and a width of the undercut region being less than a width of the wiring pattern.

### CROSS-REFERENCE TO RELATED APPLICATION

This U.S. nonprovisional application claims priority under 35 U.S.C § 119 to Korean Patent Application No. 10-2021-0130827, filed on Oct. 1, 2021, in the Korean Intellectual Property Office, the disclosure of which is hereby incorporated by reference in its entirety.

### BACKGROUND

### 1. Field

Embodiments relate to a package substrate and a semiconductor package including the same.

### 2. Description of the Related Art

Portable devices have been increasingly demanded in recent electronic product markets, and as a result, size and weight reduction of electronic parts mounted on the portable devices has been required. With the requirement of excellent performance, high speed, and compactness of electronic products, a package substrate on which a semiconductor package is mounted requires fine circuitry, superior electrical properties, excellent reliability, high speed delivery structure, and good performance.

### SUMMARY

According to some embodiments, a package substrate may include a dielectric layer; a conductive pad and a wiring pattern on the dielectric layer; a protection layer on the dielectric layer, the protection layer covering the wiring pattern; and an undercut region between a top surface of the dielectric layer and a bottom surface of the protection layer, the undercut region exposing a sidewall of the wiring pattern. A width of the undercut region may be less than a width of the wiring pattern.

According to some embodiments, a package substrate may include a dielectric layer; a lower conductive pad and a lower wiring pattern on a bottom surface of the dielectric layer; an upper conductive pad and an upper wiring pattern on a top surface of the dielectric layer; a lower protection layer on the bottom surface of the dielectric layer, the lower protection layer covering the lower wiring pattern and having a first opening that exposes a portion of the bottom surface of the dielectric layer; an upper protection layer on the top surface of the dielectric layer, the upper protection layer covering the upper wiring pattern and having a second opening that exposes a portion of the top surface of the dielectric layer; a lower undercut region between the dielectric layer and the lower protection layer, the lower undercut region extended from the first opening to expose a sidewall of the lower wiring pattern; and an upper undercut region between the dielectric layer and the upper protection layer, the upper undercut region extended from the second opening to expose a sidewall of the upper wiring pattern. A width of the lower undercut region may be less than a width of the lower wiring pattern.

According to some embodiments, a semiconductor package may include a package substrate having a top surface and a bottom surface that are opposite to each other; a semiconductor chip mounted on the top surface of the package substrate; a molding layer on the package substrate, the molding layer covering the semiconductor chip; and a plurality of external bonding terminals on the bottom surface of the package substrate. The package substrate may include: a dielectric layer; a plurality of lower conductive pads and a plurality of lower wiring patterns on the bottom surface of the dielectric layer; a plurality of upper conductive pads and a plurality of upper wiring patterns on the top surface of the dielectric layer; a plurality of lower plating patterns on surfaces of the lower conductive pads; a plurality of upper plating patterns on surfaces of the upper conductive pads; a lower protection layer on the bottom surface of the dielectric layer, the lower protection layer covering the lower wiring patterns and having a first opening that exposes a portion of the bottom surface of the dielectric layer; an upper protection layer on the top surface of the dielectric layer, the upper protection layer covering the upper wiring patterns and having a second opening that exposes a portion of the top surface of the dielectric layer; a plurality of lower undercut regions between the dielectric layer and the lower protection layer, the lower undercut regions extended from the first opening to expose sidewalls of the lower wiring patterns; and a plurality of upper undercut regions between the dielectric layer and the upper protection layer, the upper undercut regions extended from the second opening to expose sidewalls of the upper wiring patterns, that extend from the second opening and expose sidewalls of the upper wiring patterns between the dielectric layer and the upper protection layer. A width of each lower undercut region may be less than a width of each lower wiring pattern. A width of each upper undercut region may be less than a width of each upper wiring pattern.

### BRIEF DESCRIPTION OF THE DRAWINGS

Features will become apparent to those of skill in the art by describing in detail exemplary embodiments with reference to the attached drawings, in which:

FIG. 1 illustrates a flow chart showing a method of fabricating a package substrate according to some embodiments.

FIG. 2 illustrates a plan view showing a wiring substrate used for forming a package substrate according to some embodiments.

FIGS. 3A to 3F illustrate cross-sectional views of stages in a method of fabricating a package substrate according to some embodiments.

FIG. 4 illustrates an enlarged cross-sectional view showing section P1 of FIG. 2.

FIG. 5 illustrates an enlarged view showing section P2 of FIG. 2.

FIG. 6 illustrates an enlarged view showing section P3 of FIG. 5.

FIGS. 7A to 7D illustrate enlarged view of section P4 depicted in FIG. 6, showing a package substrate according to some embodiments.

FIG. 8 illustrates a cross-sectional view showing a semiconductor package including a package substrate according to some embodiments.

FIG. 9 illustrates an enlarged view showing section A1 of FIG. 8.

FIGS. 10A and 10B illustrate plan views showing top and bottom surfaces of a semiconductor package including a package substrate according to some embodiments.

FIG. 11 illustrates an enlarged view showing section A2 of FIG. 10B.

FIG. 12 illustrates an enlarged view showing section A3 of FIG. 11.

FIG. 13 illustrates a cross-sectional view along lines A-A′, B-B′, and C-C′ of FIG. 12.

FIGS. 14A to 14D illustrate enlarged plan views showing section A3 of FIG. 13, showing a package substrate according to some embodiments.

### DETAILED DESCRIPTION

A method of fabricating a package substrate, a package substrate, and a semiconductor package according to some embodiments will be discussed hereinafter in conjunction with the accompanying drawings.

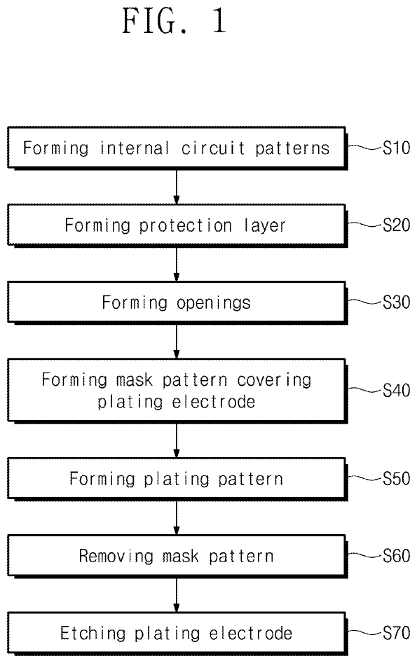

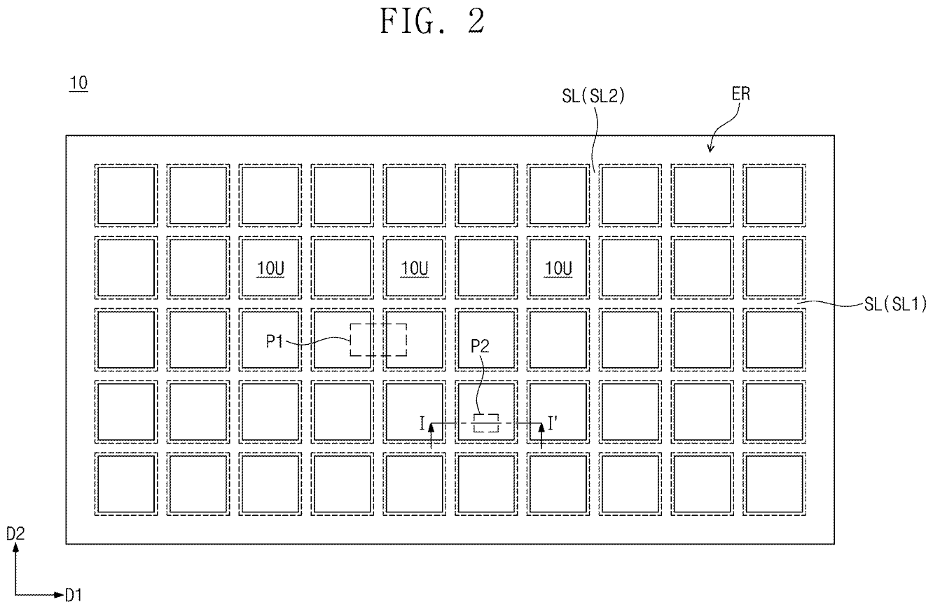

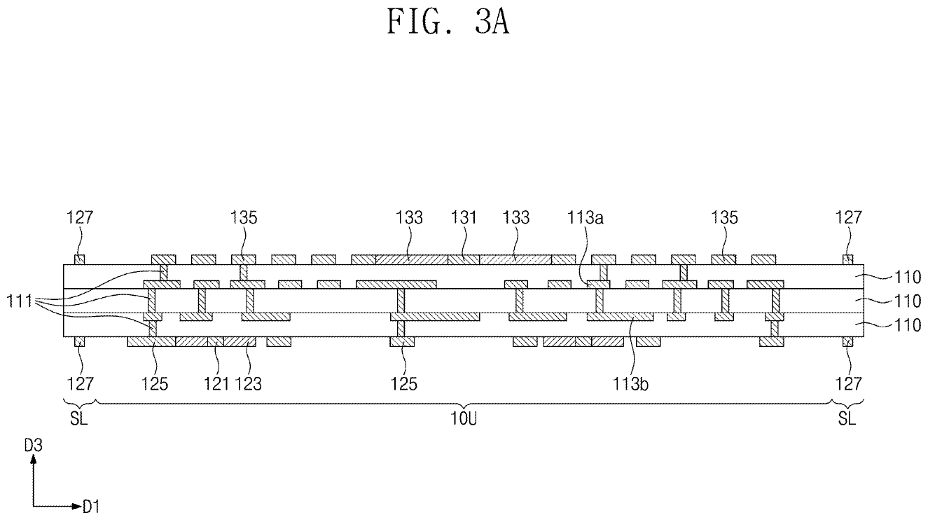

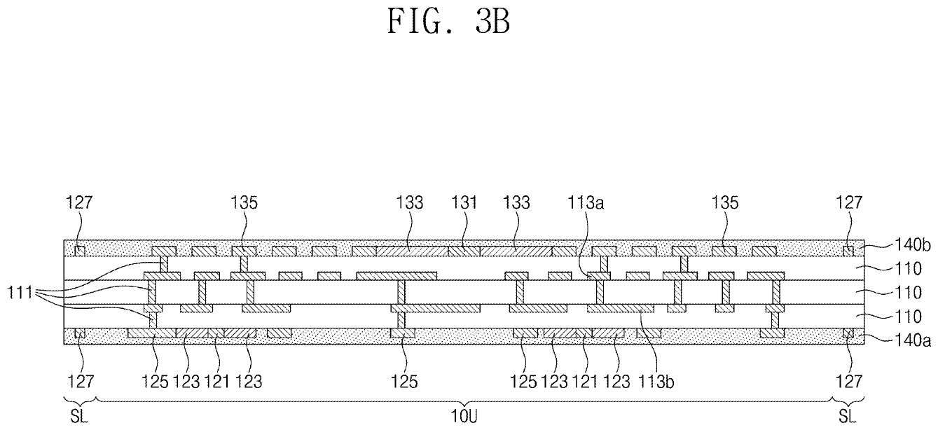

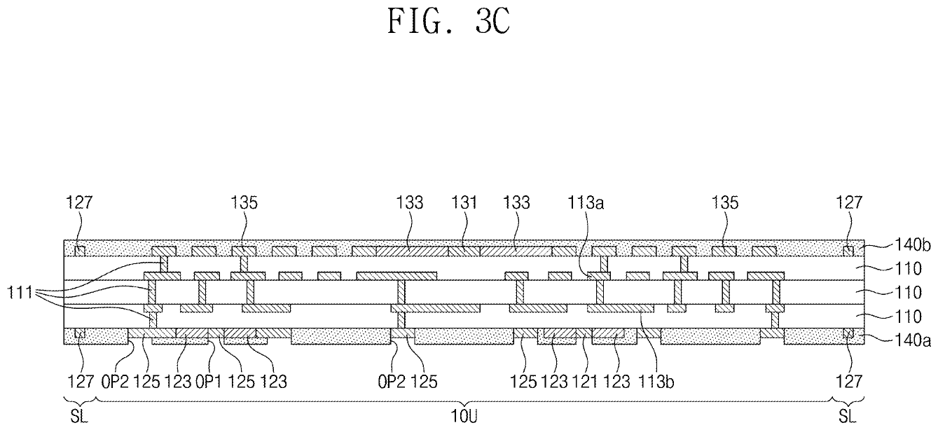

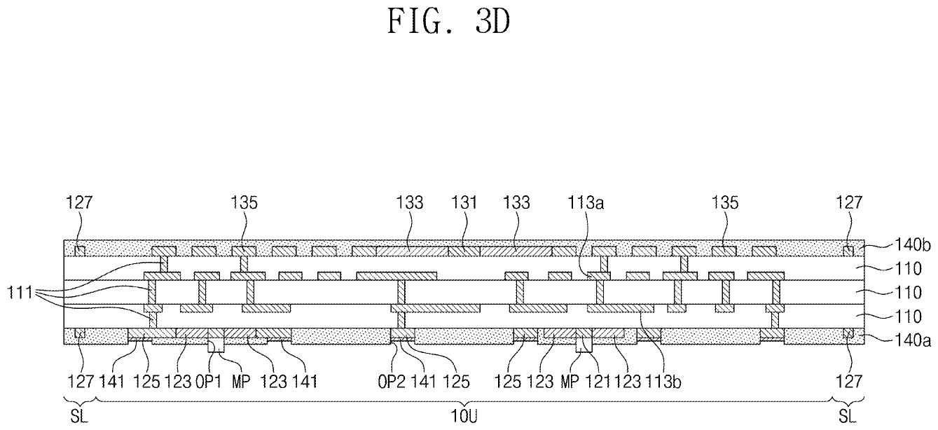

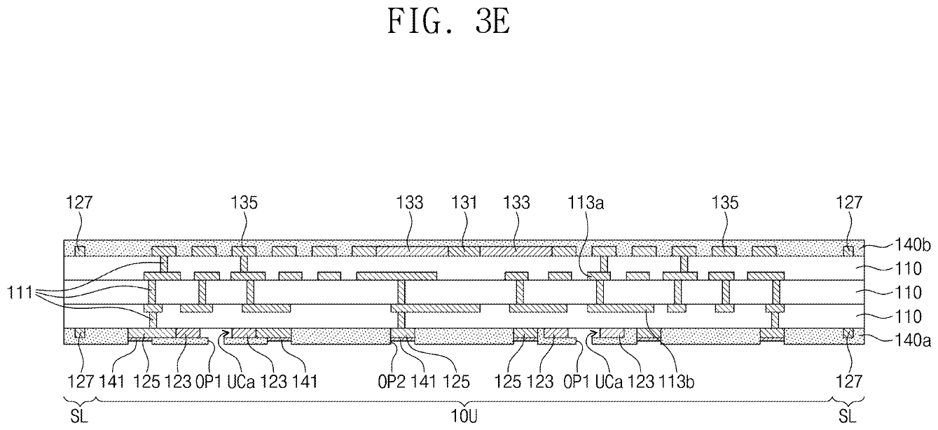

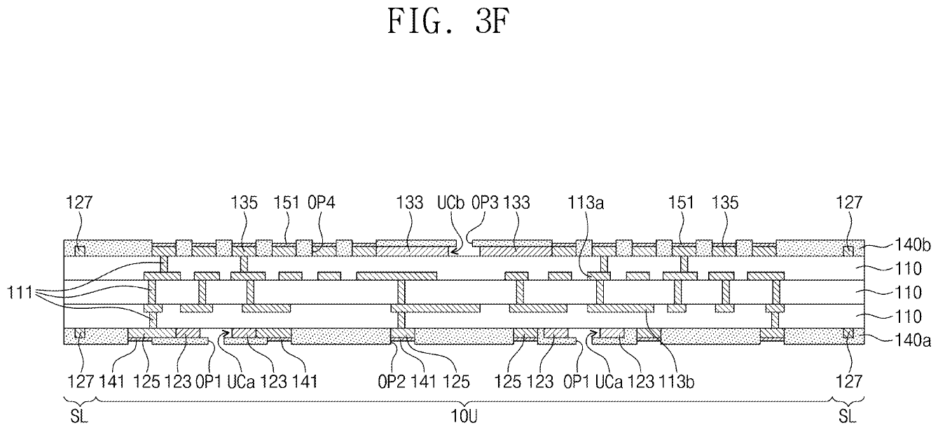

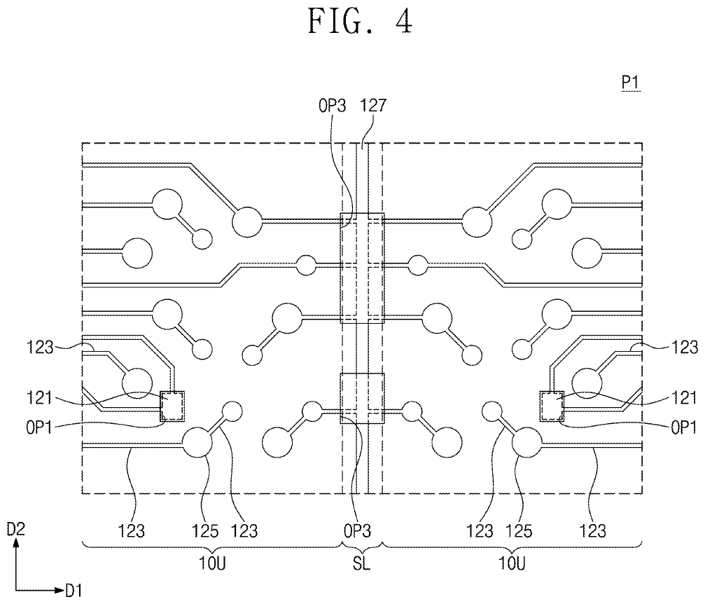

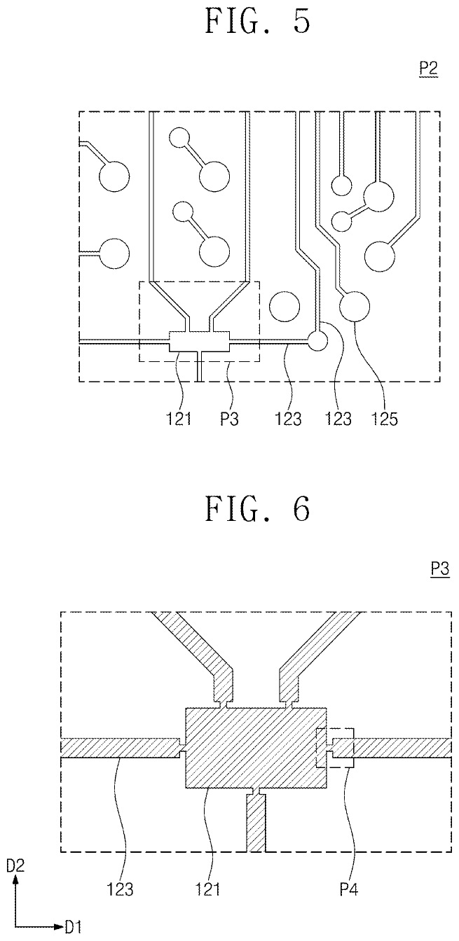

FIG. 1 illustrates a flow chart of a method of fabricating a package substrate according to some embodiments. FIG. 2 illustrates a plan view of a wiring substrate used for forming a package substrate according to some embodiments. FIGS. 3A to 3F illustrate cross-sectional views along line I-I′ of FIG. 2, showing stages in a method of fabricating a package substrate according to some embodiments. FIG. 4 illustrates an enlarged cross-sectional view of section P1 of FIG. 2. FIG. 5 illustrates an enlarged view of section P2 of FIG. 2. FIG. 6 illustrates an enlarged view of section P3 of FIG. 5.

Referring to FIGS. 1, 2, and 3A, internal circuit patterns 113a and 113b may be formed in a wiring substrate 10 (S10).

The wiring substrate 10 may include a plurality of unit regions 10U, a sawing region SL that surrounds, e.g., an entire perimeter of, each of the unit regions 10U, and an edge region ER that surrounds the, e.g., combined entire perimeter of the, unit regions 10U and the sawing region SL.

The unit regions 10U may be spaced apart from each other in a first direction D1 and/or a second direction D2. For example, the unit regions 10U may be arranged along rows parallel to the first direction D1 and along columns parallel to the second direction D2, e.g., in a matrix pattern. The first direction D1 may be parallel to a bottom surface of a dielectric layer 110. The second direction D2 may intersect the first direction D1, while being parallel to the bottom surface of the dielectric layer 110. Each of the unit regions 10U may be an area that is used as a semiconductor package substrate.

For example, the sawing region SL may surround each of the unit regions 10U. For example, the sawing region SL may include first sawing regions SL1 that extend in the first direction D1, and may also include second sawing regions SL2 that extend in the second direction D2 to run across the first sawing regions SL1. The first sawing regions SL1 may be spaced apart from each other in the second direction D2, and the second sawing regions SL2 may be spaced apart from each other in the first direction D1. A portion of the sawing region SL may be disposed between the unit regions 10U. The sawing region SL may be an area which will be removed in a subsequent sawing process, e.g., to singulate the unit regions 10U.

The internal circuit patterns 113a and 113b may be formed between the dielectric layers 110 on each unit region 10U. For example, referring to FIG. 3A, three dielectric layers 110 may be stacked along a third direction D3, with the internal circuit patterns 113a and 113b between the stacked dielectric layers 110. The third direction D3 may be a vertical direction, i.e., a direction perpendicular to a plane defined by the first and second direction D1 and D2.

Each of the dielectric layers 110 may have top and bottom surfaces that are opposite to each other, and may include a single or a plurality of dielectric layers. The dielectric layer 110 may be formed of a dielectric material, e.g., resin, and may have a thin plate shape. The resin of the dielectric layer 110 may be, e.g., a thermosetting resin, a thermoplastic resin, or any other suitable material. For example, the dielectric layer 110 may be an epoxy resin or polyimide. The epoxy resin may be, e.g., naphthalene epoxy resin, bisphenol A-type epoxy resin, bisphenol F-type epoxy resin, novolac epoxy resin, cresol novolac resin, rubber modified resin, cyclic aliphatic epoxy resin, silicone epoxy resin, nitrogen epoxy resin, or phosphorus epoxy resin. Alternatively, the dielectric layer 110 may include prepreg, Ajinomoto build-up film (ABF), flame retardant 4 (FR-4), or bismaleimide triazine (BT).

The internal circuit patterns 113a and 113b may include lower circuit patterns 113b provided on a bottom surface of one of the dielectric layers 110 and upper circuit patterns 113a provided on a top surface of the one of the dielectric layers 110. The upper and lower circuit patterns 113a and 113b may be connected to each other through via patterns 111.

The internal circuit patterns 113a and 113b may be formed by forming conductive layers on the top and bottom surfaces of one of the dielectric layers 110 and then patterning the conductive layers. The via patterns 111 may be correspondingly disposed in the dielectric layers 110 and may each be coupled to at least one of the internal circuit patterns 113a and 113b. The via patterns 111 may be formed in the dielectric layers 110 before the internal circuit patterns 113a and 113b are formed. The internal circuit patterns 113a and 113b and the via patterns 111 may include, e.g., one of copper (Cu), aluminum (Al), silver (Ag), tin (Sn), gold (Au), nickel (Ni), lead (Pb), titanium (Ti), or a combination thereof.

Afterwards, on each of the unit regions 10U, lower plating electrodes 121, lower wiring patterns 123, and lower conductive pads 125 may be formed on a bottom surface of a lowermost of the dielectric layers 110. For example, referring to FIG. 3A, at least one of the lower conductive pads 125 may be connected to one of the lower circuit patterns 113b through a via pattern 111 extending through the lowermost of the dielectric layers 110.

The lower plating electrodes 121, the lower wiring patterns 123, and the lower conductive pads 125 may be formed by forming a conductive layer on the bottom surface of the lowermost dielectric layer 110 and patterning the conductive layer. The conductive layer may be formed by using a deposition process or a plating process. The lower plating electrodes 121, the lower wiring patterns 123, and the lower conductive pads 125 may include the same metallic material. The lower plating electrodes 121, the lower wiring patterns 123, and the lower conductive pads 125 may include, e.g., one of copper (Cu), aluminum (Al), silver (Ag), tin (Sn), gold (Au), nickel (Ni), lead (Pb), titanium (Ti), or a combination thereof. The lower plating electrodes 121, the lower wiring patterns 123, and the lower conductive pads 125 may have substantially the same first thickness, e.g., along the third direction D3, and the first thickness may range from about 8 μm to about 20 μm.

According to some embodiments, at least one lower wiring pattern 123 may be connected to each of the lower plating electrodes 121. The lower plating electrodes 121 and the lower wiring pattern 123 may be connected with no boundary.

For example, referring to FIGS. 4 and 5, each of the lower plating electrodes 121 may be connected to a plurality of lower wiring patterns 123. Each of the lower plating electrodes 121 may have a tetragonal shape when viewed in plan. The lower conductive pads 125 may be disposed around each of the lower plating electrodes 121. At least one of the lower plating electrodes 121 may be disposed between neighboring lower conductive pads 125.

The lower wiring patterns 123, the lower conductive pads 125, and the lower plating electrodes 121 may be connected with no boundary, e.g., connected integrally or seamlessly. It is depicted in figures that the lower conductive pads 125, the lower wiring patterns 123, and the lower plating electrodes 121 are distinguished from each other. Each of the lower wiring patterns 123 may have a width, e.g., in the second direction D2 or in another direction in the D1-D2 plane, of, e.g., about 15 μm to about 25 μm.

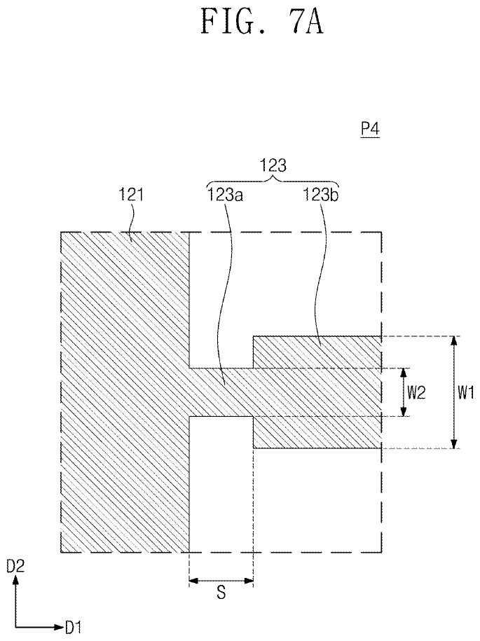

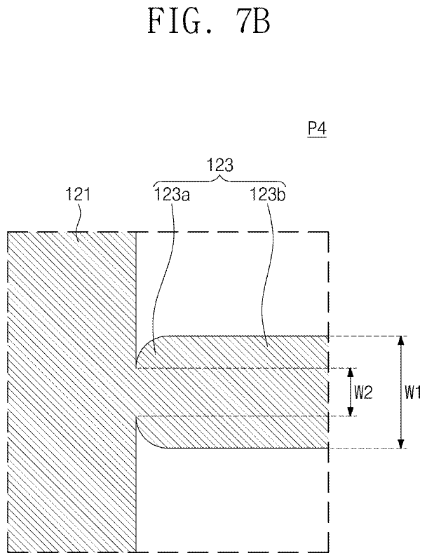

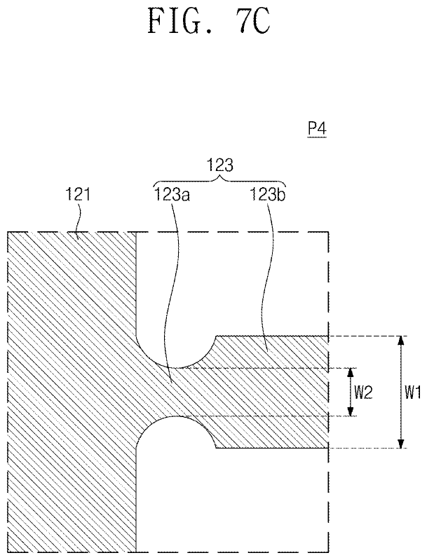

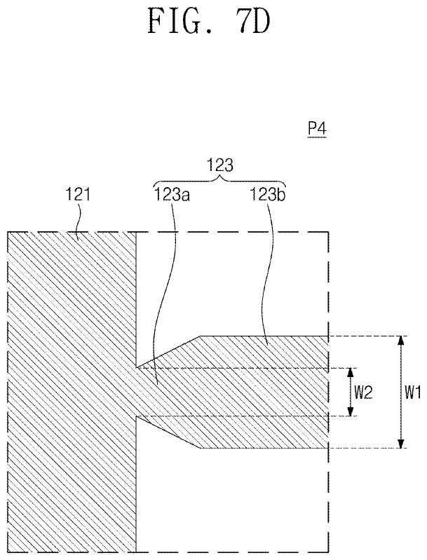

According to some embodiments, each of the lower wiring patterns 123 may have a smaller width at its portion adjacent to the lower plating electrode 121, as illustrated in FIG. 6. The lower wiring patterns 123 according to some embodiments will be described in more detail below with reference to FIGS. 6 and 7A to 7D.

Referring back to FIG. 3A, on each of the unit regions 10U, the lower conductive pads 125 may be disposed spaced apart and electrically separated from each other. The lower conductive pads 125 and the lower wiring pattern 123 may be connected with no boundary. The lower conductive pad 125 may be electrically connected through the lower wiring pattern 123 to the via pattern 111 provided in the lowermost dielectric layer 110. Therefore, the lower conductive pads 125 may be correspondingly electrically connected to upper conductive pads 135 through the internal circuit patterns 113a and 113b and the via patterns 111.

On each of the unit regions 10U, upper plating electrodes 131, upper wiring patterns 133, and the upper conductive pads 135 may be formed on a top surface of an uppermost dielectric layer 110.

The upper plating electrodes 131, the upper wiring patterns 133, and the upper conductive pads 135 may be formed by forming a conductive layer on the top surface of the uppermost dielectric layer 110 and patterning the conductive layer. The conductive layer may be formed by using a deposition process or a plating process. The upper plating electrodes 131, the upper wiring patterns 133, and the upper conductive pads 135 may include the same metallic material. The upper plating electrodes 131, the upper wiring patterns 133, and the upper conductive pads 135 may include, e.g., one of copper (Cu), aluminum (Al), silver (Ag), tin (Sn), gold (Au), nickel (Ni), lead (Pb), titanium (Ti), or a combination thereof. The upper plating electrodes 131, the upper wiring patterns 133, and the upper conductive pads 135 may have substantially the same second thickness, e.g., along the third direction D3, of about 8 μm to about 20 μm.

On each unit region 10U, at least one upper wiring pattern 133 may be connected to each of a plurality of upper plating electrodes 131. The upper plating electrodes 131 and the upper wiring pattern 133 may be connected without a boundary therebetween. The upper conductive pads 135 may be disposed around each of the upper plating electrodes 131. At least one of the upper plating electrodes 131 may be disposed between neighboring upper conductive pads 135.

The upper wiring patterns 133 and the upper conductive pads 135 may be disposed on the top surface of the uppermost dielectric layer 110. The upper wiring patterns 133 may be connected to the upper conductive pads 135 and the upper plating electrodes 131. It is depicted in figures that the upper conductive pads 135, the upper wiring patterns 133, and the upper plating electrodes 131 are distinguished from each other.

The upper conductive pads 135 may be disposed on the top surface of the uppermost dielectric layer 110. The upper conductive pads 135 may be spaced apart from and electrically connected to each other. The upper conductive pads 135 may be electrically connected to corresponding via patterns 111 provided in the uppermost dielectric layer 110. Therefore, the upper conductive pads 135 may be electrically connected to corresponding lower conductive pads 125 through the internal circuit patterns 113a and 113b and the via patterns 111.

The upper conductive pads 135 may have a pitch different from that of the lower conductive pads 125. For example, the pitch of the upper conductive pads 135 may be less than that of the lower conductive pads 125.

Referring to FIGS. 3A and 4, a plating line pattern 127 may be disposed on the sawing region SL. The plating line pattern 127 disposed on the sawing region SL may be located on the bottom surface of the lowermost dielectric layer 110 and the top surface of the uppermost dielectric layer 110. The plating line pattern 127 may be connected to the lower wiring patterns 123 or the upper wiring patterns 133 on the unit region 10U. The plating line pattern 127 may be formed simultaneously with the lower wiring patterns 123 or the upper wiring patterns 133 on the unit region 10U.

Referring to FIGS. 1, 2, and 3B, lower and upper protection layers 140a and 140b may be formed on the wiring substrate 10 (S20).

The lower and upper protection layers 140a and 140b may completely cover the wiring substrate 10. The lower protection layer 140a may cover the lower plating electrodes 121, the lower wiring patterns 123, and the lower conductive pads 125. The upper protection layer 140b may cover the upper plating electrodes 131, the upper wiring patterns 133, and the upper conductive pads 135.

A thickness of each of the lower and upper protection layers 140a and 140b, e.g., along the third direction D3, may be greater than those of the lower and upper wiring patterns 123 and 133. The thickness of each of the lower and upper protection layers 140a and 140b may range from about 8 μm to about 30 μm.

The lower and upper protection layers 140a and 140b may include a dielectric material, e.g., a solder resist. The solder resist may include, e.g., polymer or resin.

The lower and upper protection layers 140a and 140b may include fillers. The fillers may include silicon oxide, e.g., amorphous silicon oxide (SiO₂) or crystalline silicon oxide (SiO₂). Alternatively, the fillers may include at least one of aluminum oxide (Si₂O₃), magnesium oxide (MgO), zinc oxide (ZnO), silicon carbide (SiC), aluminum nitride (AlN), beryllium oxide (BeO), and boron nitride (BN). According to some embodiments, the lower and upper protection layers 140a and 140b may include a solder resist, and the fillers may include silicon oxide.

The lower and upper protection layers 140a and 140b may be formed by coating or depositing on a top surface of the dielectric layer 110, e.g., on opposite exterior surfaces of the stack of the dielectric layers 110, a precursor material in which fillers are mixed in a dielectric material, followed by curing the dielectric material. Alternatively, the lower and upper protection layers 140a and 140b may be formed by coating or depositing a dielectric material on the top surface of the dielectric layer 110, e.g., on opposite exterior surfaces of the stack of the dielectric layers 110, providing the dielectric material with fillers, and then curing the dielectric material.

Referring to FIGS. 1, 2, and 3C, first and second openings OP1 and OP2 may be formed in the lower protection layer 140a (S30).

The first openings OP1 may correspondingly expose the lower plating electrodes 121, and the second openings OP2 may correspondingly expose the lower conductive pads 125. The first and second openings OP1 and OP2 may be formed by performing exposure and development processes on the lower protection layer 140a. Each of the first openings OP1 may have a tetragonal shape and may completely expose, e.g., overlap, a top surface of a corresponding lower plating electrode 121. Each of the first openings OP1 may have a size substantially the same as or greater than that of a corresponding lower plating electrode 121.

Each of the second openings OP2 may partially or completely expose a corresponding lower conductive pad 125. Each of the second openings OP2 may have a circular or tetragonal shape.

Referring to FIGS. 1, 2, and 3D, a mask pattern MP may be formed to cover the lower plating electrodes 121 (S40).

The mask pattern MP may fill the first opening OP1 of the lower protection layer 140a. The mask pattern MP may be, e.g., a photoresist pattern. The mask pattern MP may prevent the lower plating electrodes 121 from being exposed to a plating solution in a subsequent plating process.

Afterwards, a plating process may be performed to form lower plating patterns 141 on the lower conductive pads 125 (S50).

The lower plating patterns 141 may be formed on surfaces of the lower conductive pads 125 exposed through the second openings OP2. The lower plating patterns 141 may be formed by using an electroplating process. The lower plating patterns 141 may include, e.g., tin, gold, nickel, palladium, or any alloy thereof. For example, the lower plating patterns 141 may include a nickel plating layer or a gold plating layer. The lower plating patterns 141 may each be formed to have a thickness, e.g., along the third direction D3, of about 1 μm to about 12 μm.

For example, a voltage may be applied to the lower plating electrodes 121 when the lower plating patterns 141 are formed, and a current may flow through the lower conductive pads 125 and the lower wiring patterns 123. In plating processes, the lower and upper protection layers 140a and 140b and the mask pattern MP may prevent the formation of plating layers on surfaces of the lower and upper wiring patterns 123 and 133 and of the lower and upper plating electrodes 121 and 131.

A voltage may be applied to the lower plating electrode 121 when an electroplating process is performed. After the plating process, the lower plating electrode 121 may be used as a test electrode for electrically testing the wiring substrate 10.

Referring to FIGS. 1, 2, and 3E, after the formation of the lower plating patterns 141, the mask pattern MP may be removed (S60). The mask pattern MP may be removed by an ashing process.

After that, the lower plating electrodes 121 may be removed which are exposed to the first openings OP1 (S70). A chemical etching method may be used to etch the lower plating electrodes 121.

In detail, the chemical etching method may include a dry etching method or a wet etching method. The lower plating electrodes 121 may be removed by using a plasma etching method. The removal of the lower plating electrodes 121 may allow the first opening OP1 to expose the bottom surface of the lowermost dielectric layer 110. The lower wiring patterns 123 may be divided from the lower plating electrodes 121, and the lower conductive pads 125 may be electrically separated from each other.

According to some embodiments, while the lower plating electrodes 121 are etched, an over-etching may cause a partial etching of the lower wiring patterns 123 connected to the lower plating electrodes 121. Thus, lower undercut regions UCa may be formed.

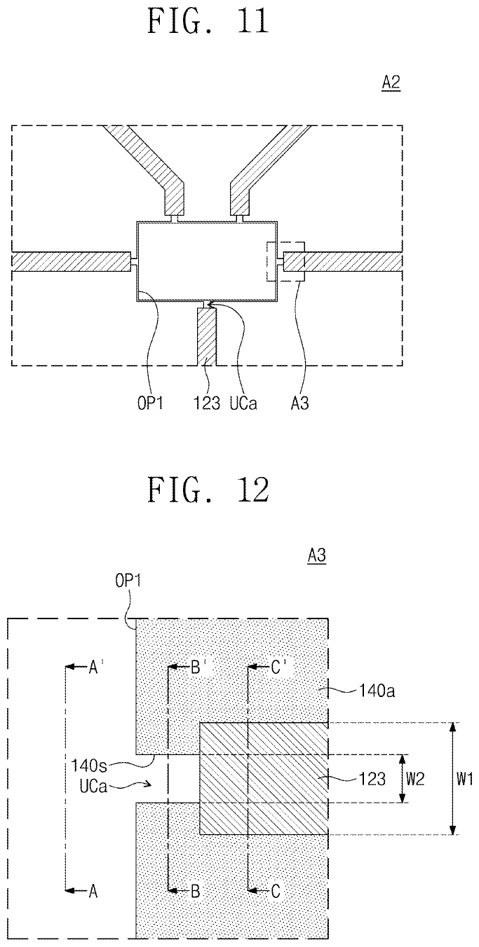

For example, each of the lower undercut regions UCa may be defined between the lower protection layer 140a and the bottom surface of the lowermost dielectric layer 110, and may expose a lateral surface of the lower wiring pattern 123 and a portion of the bottom surface of the lower protection layer 140a. For example, as illustrated in FIG. 3E, the lower undercut region UCa may be between the first opening OP1 and the lateral surface of the lower wiring pattern 123 (in a horizontal direction, as seen in a vertical cross-sectional view), e.g., so the lower undercut region Uca may not overlap the first opening OP1 in a top view. For example, as illustrated in FIG. 3E, the lower undercut region UCa may expose a surface of the lower protection layer 140a that faces the lowermost dielectric layer 110, e.g., so the surface of the lower protection layer 140a cover the entire lower undercut region UCa. The lower undercut region UCa may be connected to, e.g., in fluid communication with, the first opening OP1. In some embodiments, the first opening OP1 may be connected to a plurality of lower undercut regions UCa (FIG. 11). The lower undercut region UCa may have a width that is about 0.2 times to about 0.7 times a width of the lower wiring pattern 123, e.g., both widths being measured along a direction perpendicular to a longitudinal direction of the lower wiring pattern 123 exposed to the lower undercut wiring pattern UCa.

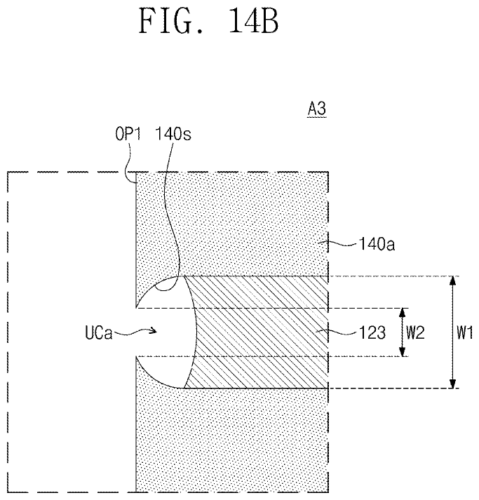

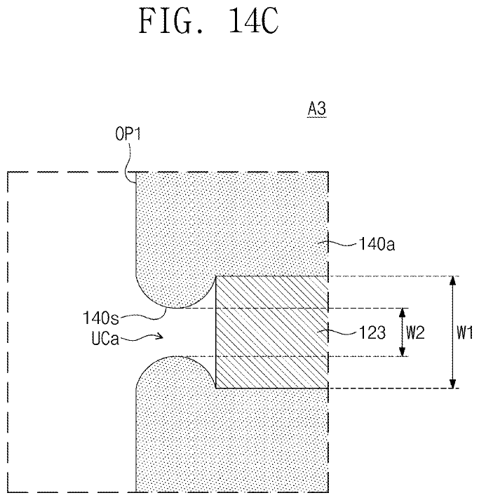

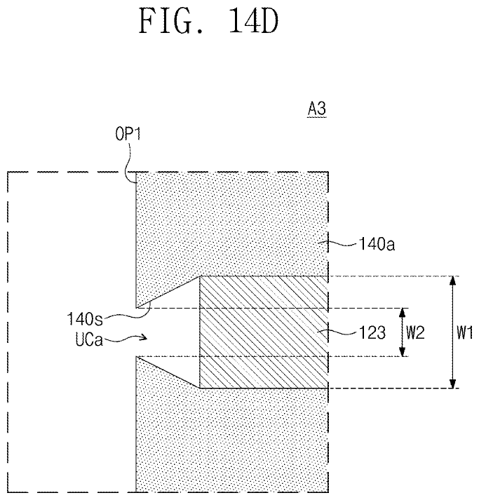

The lower undercut region UCa may have various shapes depending on conditions of an etching process that etches the lower plating electrodes 121. The shape of the lower undercut region UCa will be discussed in more detail below with reference to FIGS. 14A to 14D.

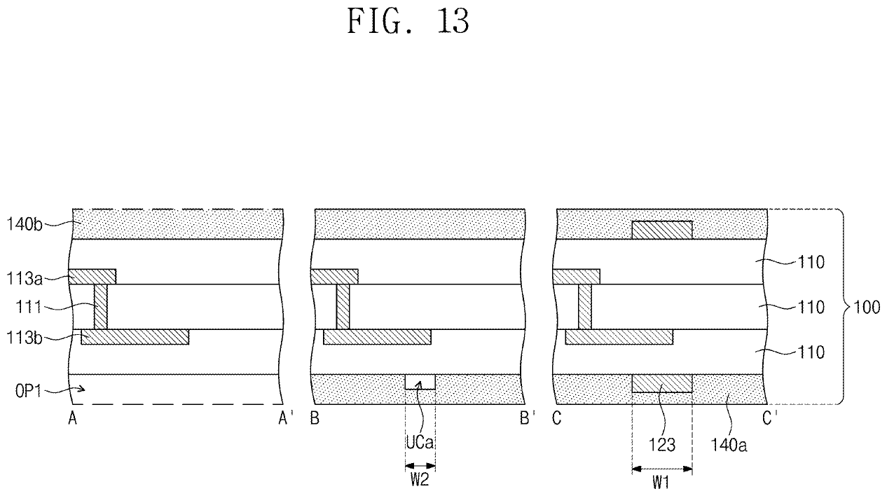

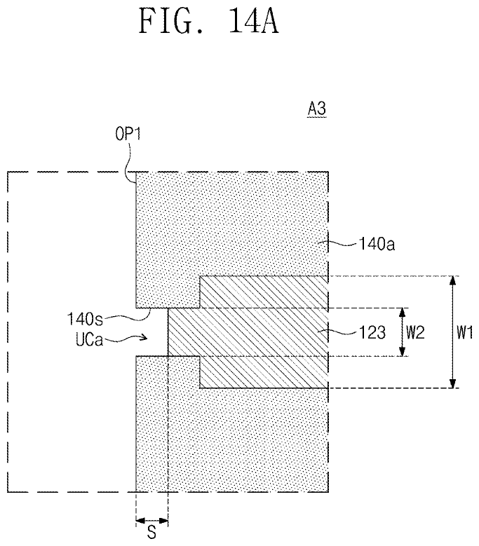

According to some embodiments, a width of the lower undercut region UCa formed by the over-etching during the removal of the lower plating electrodes 121 is less than the width of the lower wiring pattern 123, e.g., along a direction perpendicular to each of a thickness direction and a longitudinal direction of the lower wiring pattern 123 (into the page of FIGS. 13E-13F). Therefore, it may be possible to prevent the lower protection layer 140a from delamination, crack, and/or damage caused when a cleaning solution is introduced into the lower undercut region UCa in a wet cleaning process.

While the lower plating electrodes 121 are etched on the unit regions 10U, the plating line pattern 127 on the sawing region SL may also be etched.

Referring to FIGS. 1 and 3F, third and fourth openings OP3 and OP4 may be formed in the upper protection layer 140b. It is noted that operations S30 to S70 described previously with reference to the first and second openings OP1 and OP2 in the lower protection layer 140a may be repeated with reference to the third and fourth openings OP3 and OP4 in the upper protection layer 140b.

In detail, the third openings OP3 may correspondingly expose the upper plating electrodes 131, and the fourth openings OP4 may correspondingly expose the upper conductive pads 135. The formation of the third and fourth openings OP3 and OP4 in the upper protection layer 140b may include performing exposure and development processes on the upper protection layer 140b.

After the formation of the third and fourth openings OP3 and OP4, a mask pattern may be formed to cover the upper plating electrode 131. Thereafter, a plating process may be performed to form upper plating patterns 151 in the fourth openings OP4. The upper plating patterns 151 may include, e.g., tin, gold, nickel, or any alloy thereof. For example, the upper plating patterns 151 may include a nickel plating layer or a gold plating layer. The upper plating patterns 151 may each be formed to have a thickness, e.g., along the third direction D3, of about 1 μm to about 12 μm.

After the formation of the upper plating patterns 151, the upper plating electrodes 131 may be removed as discussed above with reference to FIG. 3E. A chemical etching process may be performed on the upper plating electrodes 131.

The removal of the upper plating electrodes 131 may allow the third opening OP3 to expose the top surface of the uppermost dielectric layer 110, and the upper plating electrode 131 may be divided into upper wiring patterns 133. Therefore, the upper conducive pads 135 may be electrically separated from each other.

While the upper plating electrode 131 is removed, an upper undercut region UCb between the upper protection layer 140b and the top surface of the uppermost dielectric layer 110. The upper undercut region UCb may expose a sidewall of the upper wiring pattern 133. The upper undercut region UCb may be connected to the third opening OP3. The upper undercut region UCb may have substantially the same properties as those of the lower undercut region UCa discussed above. Alternatively, the upper undercut region UCb may have a width substantially the same as that of the upper wiring pattern 133.

Afterwards, the wiring substrate 10 may undergo a sawing process performed along the sawing region SL. In the sawing process, a sawing apparatus may be used, such that the wiring substrate 10 between the unit regions 10U may be diced, e.g., cut or singulated, to form individual package substrates separated from each other. The sawing process may remove the plating line pattern 127 formed on the sawing region SL. In this case, a sawing blade or a laser may be employed in the sawing process.

In some embodiments, a semiconductor chip may be mounted on each unit region 10U of the wiring substrate 10. A molding layer may be formed on the wiring substrate 10, and then the sawing process may be performed.

FIG. 6 illustrates an enlarged view of section P3 of FIG. 5, which is an enlarged plan view of a connection between the lower plating electrode 121 and the wiring patterns 123. FIGS. 7A to 7D illustrate enlarged view of section P4 in FIG. 6, showing a package substrate according to some embodiments.

Referring to FIGS. 7A to 7D, as discussed above, a plurality of the lower wiring patterns 123 may be connected to each lower plating electrode 121. Each of the lower wiring patterns 123 may include a wire part 123b having a first width W1 and a connection part 123a having a second width W2 less than the first width W1, e.g., the widths being measured along a direction perpendicular to a longitudinal direction of the lower wiring pattern 123. The connection part 123a may be provided between the lower plating electrode 121 and the wire part 123b. The first width W1 may range from about 15 μm to about 25 and the second width W2 may be about 0.2 times to about 0.7 times the first width W1.

According to the embodiment shown in FIG. 7A, the wire part 123b and the connection part 123a may each have a substantially uniform width, e.g., in the second direction D2. In addition, the connection part 123a may have a length S (or a distance between the wire part 123b and the lower plating electrode 121) substantially the same as or greater than the second width W2 of the connection part 123a.

According to the embodiment shown in FIG. 7B, the wire part 123b may have a substantially uniform width W1, e.g., in the second direction D2, and the connection part 123a may have a width that has a minimum value (or the second width W2) at a portion in contact with the lower plating electrode 121 and monotonously, e.g., gradually, increases in a direction from the lower plating electrode 121 toward the wire part 123b. The connection part 123a of the lower wiring pattern 123 may have a rounded lateral surface.

According to the embodiment shown in FIG. 7C, the connection part 123a may have a width that has a minimum value (or the second width W2) at an intermediate portion between the lower plating electrode 121 and the wire part 123b and gradually increases in directions approaching the lower plating electrode 121 and the wire part 123b. The connection part 123a of the lower wiring pattern 123 may have a bottleneck shape. The wire part 123b may have constant width W1.

According to the embodiment shown in FIG. 7D, the connection part 123a may have a width that has a minimum value (or the second width W2) at a portion in contact with the lower plating electrode 121 and monotonously increases in a direction from the lower plating electrode 121 toward the wire part 123b. The connection part 123a of the lower wiring pattern 123 may have a linear lateral surface, e.g., inclined at an oblique angle relative to the lower plating electrode 121 (top view). The wire part 123b may have a constant with W1.

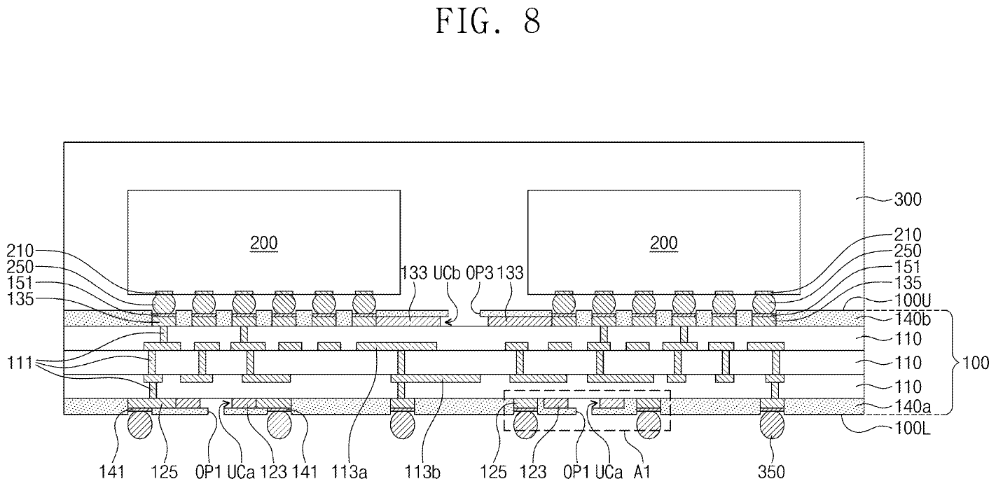

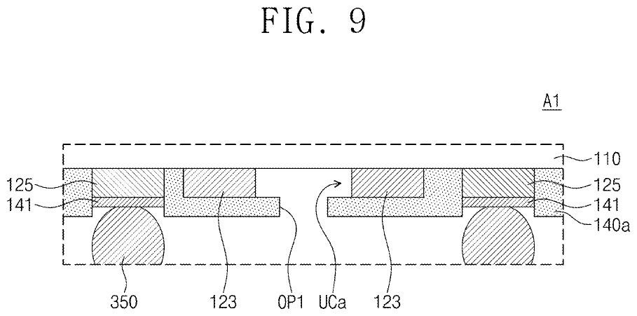

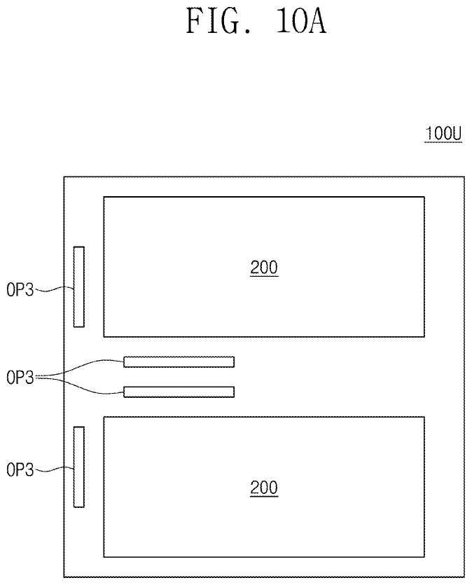

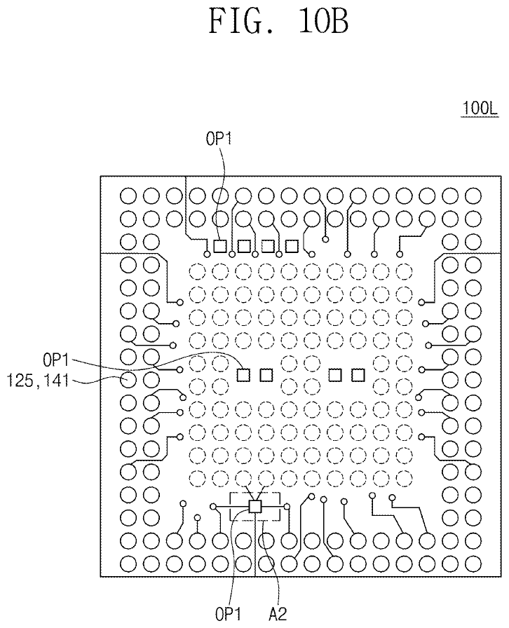

FIG. 8 illustrates a cross-sectional view of a semiconductor package including a package substrate according to some embodiments. FIG. 9 illustrates an enlarged view showing section A1 of FIG. 8. FIGS. 10A and 10B illustrate plan views showing top and bottom surfaces of a semiconductor package including a package substrate according to some embodiments. FIG. 11 illustrates an enlarged view showing section A2 of FIG. 10B. FIG. 12 illustrates an enlarged view showing section A3 of FIG. 11. FIG. 13 illustrates a cross-sectional view along lines A-A′, B-B′, and C-C′ of FIG. 12.

Referring to FIGS. 8, 9, 10A, and 10B, a semiconductor package may include a package substrate 100, at least one semiconductor chip 200, and a molding layer 300.

As discussed above with reference to FIGS. 3A to 3F, the package substrate 100 may be substantially the same as the wiring substrate 10 and include the dielectric layers 110, the via patterns 111, the internal circuit patterns 113a and 113b, the lower and upper wiring patterns 123 and 133, the lower and upper conductive pads 125 and 135, and the lower and upper plating patterns 141 and 151. In addition, the package substrate 100 may include the lower and upper protection layers 140a and 140b.

As discussed above, the package substrate 100 may be defined between the lower protection layer 140a and the lowermost dielectric layer 110, and may include the lower undercut region UCa connected to the first opening OP1. Moreover, the package substrate 100 may be defined between the upper protection layer 140b and the top surface of the uppermost dielectric layer 110, and may include the upper undercut region UCb connected to the third opening OP3.

Referring to FIGS. 8 and 10A, when viewed in plan, the upper undercut region UCb and the third openings OP3 provided in the upper protection layer 140b may be positioned around the semiconductor chips 200 and covered with the molding layer 300.

Referring to FIGS. 8 and 10B, on a bottom surface 100L of the package substrate 100, one of the first openings OP1 may be provided between external input/output terminals 350 that are adjacent to each other.

The lower undercut region UCa and the first openings OP1 provided in the lower protection layer 140a of the package substrate 100 may be positioned between the lower conductive pads 125 that are adjacent to each other. The lower undercut region UCa may extend from the first opening OP1 to expose a sidewall of the lower wiring pattern 123, e.g., the lower undercut region UCa may extend laterally from the first opening OP1 toward the lower wiring patterns 123 (FIG. 11). The first opening OP1 and the lower undercut region UCa may be exposed to the atmosphere, e.g., to an exterior of the package.

Referring to FIGS. 11, 12, and 13, the lower wiring patterns 123 may have their distal ends that are disposed around the first opening OP1. The lower undercut regions UCa may be correspondingly disposed between the first opening OP1 and each of the distal ends of the lower wiring patterns 123 (FIG. 11).

As illustrated in FIG. 12, the lower wiring patterns 123 may each have a first width W1, and the lower undercut regions UCa may each have a second width W2 less than the first width W1, e.g., the widths being measured along a direction perpendicular to a longitudinal direction of the lower wiring pattern 123. The first width W1 may range from about 15 μm to about 25 μm, and the second width W2 may be about 0.2 times to about 0.7 times the first width W1.

The lower undercut regions UCa may each have the second width W2 that is uniform between the lower wiring pattern 123 and the first opening OP1. In this case, the lower protection layer 140a may have a lateral surface 140s exposed to, e.g., facing, the lower undercut region UCa, and the lateral surface 140s may be linear or flat. The lower undercut region UCa and the lower wiring pattern 123 will be described in more detail below with reference to FIGS. 14A to 14D.

Referring back to FIG. 8, the semiconductor chip 200 may be mounted on the package substrate 100. According to some embodiments, a plurality of semiconductor chips 200 may be provided on a top surface 100U of the package substrate 100.

A plurality of chip pads 210 may be disposed on a bottom surface of each semiconductor chip 200. The semiconductor chip 200 may be disposed to allow its bottom surface to face the top surface 100U of the package substrate 100, and the chip pads 210 of the semiconductor chip 200 may be connected to the upper wiring patterns 133 of the package substrate 100. A plurality of connection terminals 250 may be attached between the chip pads 210 of the semiconductor chip 200 and the upper plating patterns 151 of the package substrate 100.

The molding layer 300 may cover the semiconductor chip 200 on the package substrate 100. The molding layer 300 may be in direct contact with a top surface of the upper protection layer 140b of the package substrate 100. The molding layer 300 may be provided on the top surface 100U of the package substrate 100, and may cover a sidewall and a top surface of the semiconductor chip 200. The molding layer 300 may include a dielectric polymer, e.g., an epoxy-based molding compound.

In some embodiments, an under-fill layer may be provided in a gap between the package substrate 100 and the semiconductor chip 200, encapsulating the connection terminals 250. In this case, the upper undercut region UCb may be filled with the under-fill layer. The under-fill layer may include, e.g., a dielectric polymer or a dielectric film. For example, the under-fill layer may include an epoxy-based polymer.

The external input/output terminals 350 may be attached to the lower plating patterns 141 of the package substrate 100. The external input/output terminals 350 may be, e.g., solder balls or bumps. The external input/output terminals 350 may be disposed on the bottom surface 100L of the package substrate 100. For example, the external input/output terminals 350 may be correspondingly disposed on the lower plating patterns 141 and correspondingly coupled to the lower conductive pads 125. The external input/output terminals 350 may be solder balls and may include metal, e.g., a solder material. The solder material may include one or more of, e.g., tin (Sn), silver (Ag), zinc (Zn), and any alloy thereof.

FIGS. 14A to 14D illustrate enlarged plan views of section A3 of FIG. 13, showing a package substrate according to some embodiments.

Referring to FIG. 14A, each of the lower wiring patterns 123 may include a first part having a first width W1 and a second part, which is connected to the first part, having a second width W2 less than the first width W1.

The lower undercut region UCa may be disposed between the first opening OP1 and the distal ends of the lower wiring patterns 123. The lower undercut region UCa may have the second width W2 (i.e., the same width as the second part of the lower wiring pattern 123). The lower undercut region UCa may have a length S less than the second width W2 of the lower undercut region UCa.

Referring to FIG. 14B, the lower undercut region UCa may be disposed between the first opening OP1 and the distal ends of the lower wiring patterns 123.

The lower undercut region UCa may have a minimum width, or a second width W2, at a portion adjacent to the first opening OP1. The lower undercut region UCa may have a width that monotonously increases in a direction from the first opening OP1 toward the lower wiring pattern 123. The lower wiring pattern 123 may be rounded at its sidewall exposed to the lower undercut region UCa. The lower undercut region UCa may expose a rounded lateral surface 140s of the lower protection layer 140a.

Referring to FIG. 14C, the lower undercut region UCa may have a width that has a minimum value, or a second width W2, at an intermediate portion between the first opening OP1 and the lower wiring pattern 123 and gradually increases in directions approaching the first opening OP1 and the lower wiring pattern 123. For example, the lower undercut region UCa may have a bottleneck shape. The lower undercut region UCa may expose a rounded lateral surface 140s of the lower protection layer 140a.

Referring to FIG. 14D, the lower undercut region UCa may a width that has a minimum value, at a second width W2, at a portion adjacent to the first opening OP1 and monotonously increases in a direction approaching the lower wiring pattern 123. The lower undercut region UCa may expose a linear or flat lateral surface 140s of the lower protection layer 140a.

By way of summation and review, embodiments provide a package substrate with increased reliability, as well as a semiconductor package with increased reliability. That is, according to some embodiments, sizes of undercut regions exposed to openings of lower and upper protection layers may be minimized, e.g., a width of the lower undercut region UCa may be smaller than the width of the lower wiring pattern 123, thereby substantially reducing or preventing the lower and upper protection layers from damage, cracking, and/or delamination that are produced in a cleaning process performed on a package substrate.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A package substrate, comprising:
a dielectric layer;
a conductive pad and a wiring pattern on the dielectric layer;
a protection layer on the dielectric layer, the protection layer covering the wiring pattern; and
an undercut region between facing surfaces of the dielectric layer and the protection layer, the undercut region exposing a sidewall of the wiring pattern, and a width of the undercut region being less than a width of the wiring pattern.

2. The package substrate as claimed in claim 1, wherein:
the protection layer has a first opening that exposes a portion of the dielectric layer, and
the undercut region is connected to the first opening.

3. The package substrate as claimed in claim 1, wherein the width of the undercut region decreases with increasing distance from the wiring pattern.

4. The package substrate as claimed in claim 1, wherein a portion of the protection layer facing the undercut region has a rounded sidewall.

5. The package substrate as claimed in claim 1, wherein:
the wiring pattern has a same thickness as the conductive pad, and
the wiring pattern includes a same material as the conductive pad.

6. The package substrate as claimed in claim 1, wherein the width of the undercut region is about 0.2 times to about 0.7 time the width of the wiring pattern.

7. The package substrate as claimed in claim 1, wherein the width of the wiring pattern is in a range of about 15 μm to about 25 μm.

8. The package substrate as claimed in claim 1, further comprising a plating pattern on the conductive pad, the protection layer having a second opening exposing the plating pattern on the conductive pad.

9. The package substrate as claimed in claim 8, wherein the plating pattern includes a metallic material different from a metallic material of the conductive pad.

10. A package substrate, comprising:
a dielectric layer;
a lower conductive pad and a lower wiring pattern on a bottom surface of the dielectric layer;
an upper conductive pad and an upper wiring pattern on a top surface of the dielectric layer;
a lower protection layer on the bottom surface of the dielectric layer, the lower protection layer covering the lower wiring pattern and having a first opening that exposes a portion of the bottom surface of the dielectric layer;
an upper protection layer on the top surface of the dielectric layer, the upper protection layer covering the upper wiring pattern and having a second opening that exposes a portion of the top surface of the dielectric layer;
a lower undercut region between the dielectric layer and the lower protection layer, the lower undercut region extending from the first opening to expose a sidewall of the lower wiring pattern, and a width of the lower undercut region being less than a width of the lower wiring pattern; and
an upper undercut region between the dielectric layer and the upper protection layer, the upper undercut region extending from the second opening to expose a sidewall of the upper wiring pattern.

11. The package substrate as claimed in claim 10, wherein a width of the upper undercut region is less than a width of the upper wiring pattern.

12. The package substrate as claimed in claim 10, wherein the width of the lower undercut region gradually decreases in a direction toward the first opening from the sidewall of the lower wiring pattern.

13. The package substrate as claimed in claim 10, wherein a portion of the lower protection layer facing the lower undercut region has a rounded sidewall.

14. The package substrate as claimed in claim 10, wherein the lower protection layer and the upper protection layer include a solder resist.

15. The package substrate as claimed in claim 10, wherein each of the lower conductive pad, the upper conductive pad, the lower wiring pattern, and the upper wiring pattern includes copper.

16. The package substrate as claimed in claim 10, further comprising:
a lower plating pattern on the lower conductive pad, the lower protection layer including a third opening that exposes the lower plating pattern on the lower conductive pad; and
an upper plating pattern on the upper conductive pad in the fourth opening, the upper protection layer including a fourth opening that exposes the upper plating pattern on the upper conductive pad.

17. The package substrate as claimed in claim 16, wherein the lower plating pattern and the upper plating pattern include a metallic material different from a metallic material of the lower conductive pad and the upper conductive pad.

18. A semiconductor package, comprising:
a package substrate having a top surface and a bottom surface that are opposite to each other;
a semiconductor chip mounted on the top surface of the package substrate;
a molding layer on the package substrate, the molding layer covering the semiconductor chip; and
external bonding terminals on the bottom surface of the package substrate,
wherein the package substrate includes:
a dielectric layer,
lower conductive pads and lower wiring patterns on a bottom surface of the dielectric layer,
upper conductive pads and upper wiring patterns on a top surface of the dielectric layer,
lower plating patterns on the lower conductive pads,
upper plating patterns on the upper conductive pads,
a lower protection layer on the bottom surface of the dielectric layer, the lower protection layer covering the lower wiring patterns and having a first opening that exposes a portion of the bottom surface of the dielectric layer,
an upper protection layer on the top surface of the dielectric layer, the upper protection layer covering the upper wiring patterns and having a second opening that exposes a portion of the top surface of the dielectric layer,
lower undercut regions between the dielectric layer and the lower protection layer, the lower undercut regions extending from the first opening to expose sidewalls of the lower wiring patterns, and a width of each of the lower undercut regions is less than a width of each of the lower wiring patterns, and
upper undercut regions between the dielectric layer and the upper protection layer, the upper undercut regions extending from the second opening to expose sidewalls of the upper wiring patterns, and a width of each of the upper undercut regions is less than a width of each of the upper wiring patterns.

19. The semiconductor package as claimed in claim 18, wherein one of the lower undercut regions is between adjacent ones of the external bonding terminals.

20. The semiconductor package as claimed in claim 18, wherein the molding layer fills the upper undercut regions.
